(19) United States
(12) Patent Application Publication
(10) Pub. No.: US 2014/0251406 A1
(43) Pub. Date: Sep. 11, 2014

(54) Multi-Purpose High Performance Thermoelectric Module

(71) Applicants: Wen-Pin Chen, New Taipei City (TW); Chiu-Yueh Tung, New Taipei City (TW)

(72) Inventors: Wen-Pin Chen, New Taipei City (TW); Chiu-Yueh Tung, New Taipei City (TW)

(21) Appl. No.: 13/789,654

(22) Filed: Mar. 7, 2013

(51) Int. Cl. H01L 35/30

(52) U.S. Cl. CPC H01L 35/30
USPC 136/230

(57) ABSTRACT

This invention provides a multi-purpose high performance thermoelectric module, comprising: A first impeller; a second impeller at the opposite side of the first impeller; Two FPCBs respectively positioned between the first and second impellers; Multiple T.E elements located between the two FPCBs, and combine with the first and second impellers to form a thermoelectric module; A shaft at the outer end of the second impeller; Two slip rings located at the insulation layer of the shaft; Two wires inside the shaft, with the two ends of the wires respectively attached to the ends of the T.E elements and two slip rings for connection; and two brushes installed at the slip ring. With this design, the present invention is able to convert the existing kinetic energy within the waste heat into the required rotational energy for the thermoelectric module and achieve the heat dissipation performance of a fan.

### SUMMARY OF THE INVENTION

The purpose of this present invention is to provide an improved structural multi-purpose high performance thermoelectric module to overcome the difficulties with the current technology.

The present invention is directed to solve the problem of the customary thermoelectric modules, in which T.E elements of phosphorus (P) and nitrogen (N) are soldered in series to aluminum oxide or ceramic substrate to create a thermoelectric module set. Based to the purpose and application with this customary thermoelectric module, heat dissipation fins and an electric fan are respectively added to the cold and hot ends of the device. When it is used for heat and electricity conversion, the system turns into a bulky assembly, with complicated and expensive wiring, piping, pumps and control circuits, and having a low overall performance. In addition, as this type of operating module is stationary, the thermoelectric modules are to be tightly fixed to the large cooling fins for gas cooling applications, and require two sets of strong fans to enable module operation; when it is used for liquid cooling applications, the customary device requires complex circulation mechanisms, pumps, fan and so on. The uneconomic costs, bulk sizes and energy consumption during operations results with low performance.

In order to achieve the previous disclosed purposes, this present invention provides a multi-purpose high performance thermoelectric module, comprising:

A first impeller with multiple blades, with the blades positioned at the end surface of a centrifugal fan, and having slots between the impeller blades;

A second impeller located at the opposite side of the first impeller, with its multiple blades corresponding to the slots of the first impeller blades, and positioned at the end surface of a centrifugal fan;

Two FPCBs which are respectively installed between the first and second impellers, with said FPCB having slots corresponding to the blades of the second impeller;

Multiple T.E elements installed between the two FPCBs, in which the T.E elements of P and N-type materials are soldered in sequence to the FPCBs of the first and second impellers by reflow, and forming the thermoelectric module;

A shaft at the outer end of the second impeller, a thermally conductive rod shape, which includes an axial perforating aperture and insulation layer respectively at the center and rim;

Two slip rings located at the insulation layer of the shaft as conductive annular bodies;

Two wires inside the aperture of the shaft, with the two ends of the wires respectively attached to the ends of the T.E elements and two slip rings for connection;

and two brushes installed at the slip ring to form a loop with the external circuit.

More preferably, the first impeller is made from a metal material.

Still more preferably, the second impeller is also made from metal material.

To achieve the above purpose, this present invention provides a multi-purpose high performance thermoelectric module, comprising:

A first impeller with multiple blades, with the blades positioned at the external sides of an axial fan;

A second impeller located at the opposite side of the first impeller, with its multiple blades corresponding to the first impeller blades, and positioned at the external sides of an axial fan;

Two FPCBs which are respectively installed between the first and second impellers;

Multiple T.E elements installed between the two FPCBs, in which T.E elements of P and N-type materials are soldered in sequence to the FPCBs of the first and second impellers by reflow, and forming the thermoelectric module;

A shaft at the outer end of the second impeller, a thermally conductive rod shape, which includes an axial perforating aperture and insulation layer respectively at the center and rim;

Two slip rings located at the insulation layer of the shaft as conductive annular bodies;

Two wires inside the aperture of the shaft, with the two ends of the wires respectively attached to the ends of the T.E elements and two slip rings for connection;

and two brushes installed at the slip ring to form a loop with the external circuit.

More preferably, the first impeller is made from a metal material.

Still more preferably, the second impeller is also made from a metal material.

And even more preferably in the present invention, the blades among the first and second impellers are arranged in a cross-sequence structure.

With this design, the present invention is able to convert the existing kinetic energy within the waste heat into the required rotational energy for the thermoelectric module and achieve the heat dissipation performance of a fan. The design consumes no external electricity, saves saving, reduces carbon emission, and enhances the scope of applications and performance.

### BRIEF DESCRIPTION OF THE DRAWINGS

FIG. 1 is an exploded view of the present invention wherein the impeller blades form a centrifugal structure for the thermoelectric module.

FIG. 2 is a structural assembly drawing of the present invention wherein the impeller blades form a centrifugal structure for the thermoelectric module.

FIG. 3 is a cross section drawing of the present invention.

FIG. 4 shows the air flow turbulence created by the present invention in its centrifugal structure and cross-blade structure.

FIG. 5 is an exploded view of the present invention wherein the impeller blades form a cross-blade structure for the thermoelectric module.

FIG. 6 is an exploded view of the present invention wherein the impeller blades form an axial and cross-blade structure.

FIG. 6A is an assembly drawing of the present invention wherein the impeller blades form an axial and cross-blade structure.

FIG. 7 is an exploded view of the present invention wherein the impeller blades form an axial and cross-blade structure.

FIG. 7A is an assembly drawing of the present invention wherein the impeller blades form an axial and sequence structure.

FIG. 8 is an exploded view of the present invention wherein the impeller blades form an axial structure for the thermoelectric module.

FIG. 9 is a Condensation Comparison Table (relative humidity, environmental temperature, and condensation temperature).

### DESCRIPTION OF MAIN COMPONENT SYMBOLS

The reference numerals identify the respective structural elements of the invention:
100 . . . Thermoelectric module
1 . . . First impeller
11 . . . Impeller blade
12 . . . Slot
2 . . . Second impeller
21 . . . Impeller blade
3 . . . FPCB
31 . . . Slot
4 . . . FPCB
41 . . . Slot
5 . . . T.E element
6 . . . Shaft
61 . . . Aperture
62 . . . Insulation layer
7 . . . Slip ring
8 . . . Wire
9 . . . Brush

### DETAILED DESCRIPTION OF THE PREFERRED EMBODIMENTS

The previous description of the present invention and its other technological descriptions, characteristics and performances are described in detail with the drawings of a preferred embodiment. The drawings are for the purpose of illustration only and do not limit the specific ratio and precise layout of the invention. Accordingly, the scope of protection is not limited to the ratio and layout to the embodiment drawings of this present invention.

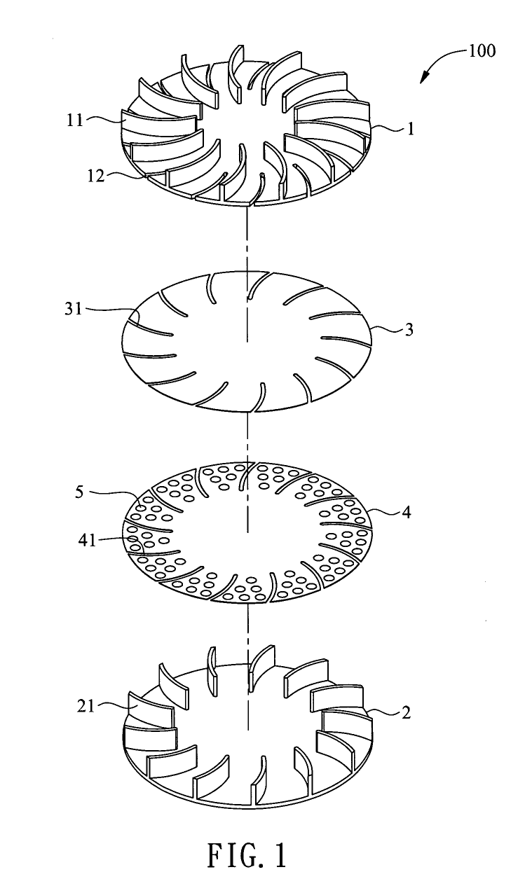

Referring to FIGS. 1, 2, 3 and 4 which shows a preferred embodiment of this present invention, the multi-purpose high performance thermoelectric module includes a first impeller 1, a second impeller 2, two FPCBs 3, 4, multiple T.E elements 5, a shaft 6, two slip rings 7, two wires 8, and two brushes 9.

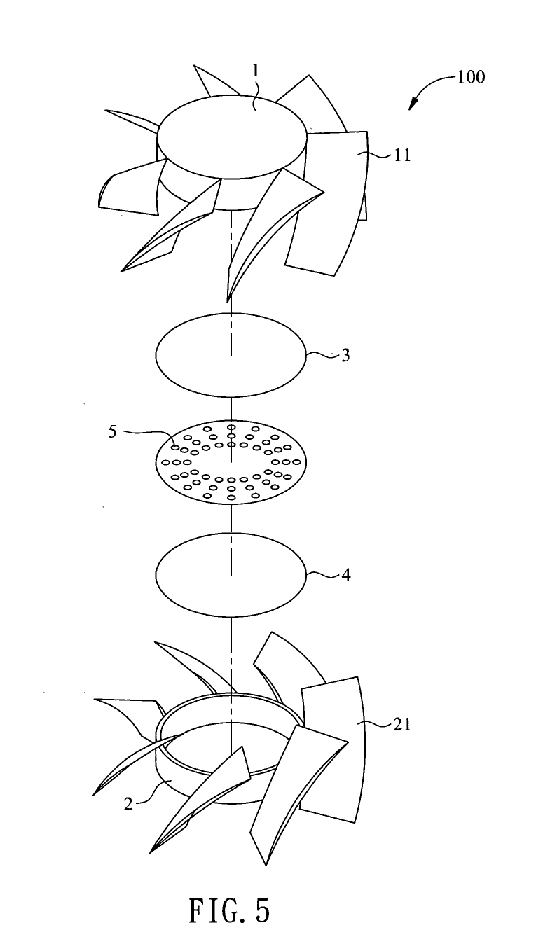

The previously described first impeller 1 includes multiple impeller blades 11 adapted to effectively utilize the waste heat in the embodiment. The blades 11 are made from metal materials with good conductivity. However, the present invention is not limited to only metal, and may apply to any conductive materials to be within the scope of protection. Moreover, the impeller blades 11 of the first impeller 1 are located at the end surface of the centrifugal fan (as in FIGS. 1 & 2, forming long impeller blades 11) or at the external sides of an axial fan (as shown in FIGS. 5, 6, 6A, 7, 7A and 8). To provide the centrifugal fan its structure, short slots 12 may be applied between the impeller blades 11 of the first impeller 1.

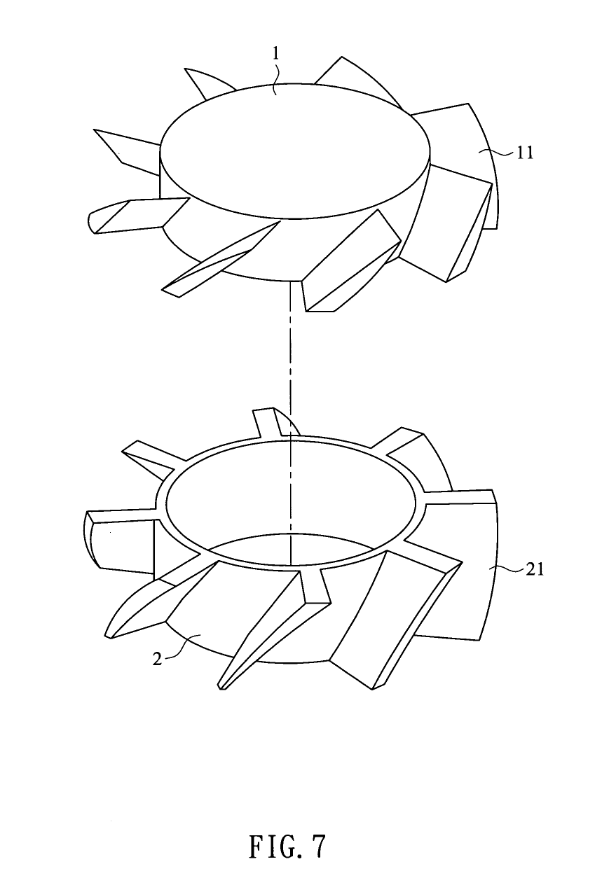

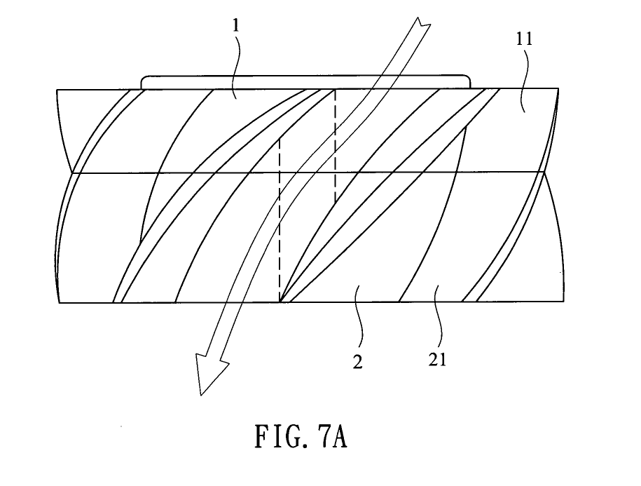

The previously described second impeller 2 is located on the opposite side of the first impeller 1, having multiple blades 21 which corresponds to the impeller blades 11 of the first impeller 1. In order to effectively utilize waste heat, the said blades are also made from metal materials with good conductivity. However, the present invention is not limited to only metal, and may apply to any conductive materials to be within the scope of protection. Moreover, the impeller blades 21 of the second impeller 2 are either positioned at the end surface of a centrifugal fan (as in FIGS. 1 & 2, the short impeller blades 21 are located at the corresponding position between the impeller blades 11 and slots 12 of the first impeller 1) or at the external sides of an axial fan (as shown in FIGS. 5, 6, 6A, 7, 7A and 8). The blades 21 of the second impeller 2 and the blades 11 of the first impeller 1 are arranged in a cross structure (as in FIGS. 1, 2, 4, 5, 6 and 6A) and sequence (as in FIG. 7).

The previously described FPCBs 3, 4 are respectively positioned between the first impeller 1 and second impeller 2. Furthermore, the FPCBs 3, 4 in this present invention are extremely thin and flexible substrates, attached by thermal conductive adhesive to the thermally conductive body to form fan-shaped objects which corresponds to the first impeller 1 and second impeller 2. The surface bottom is cleaned prior to the attachment. The FPCBs 3, 4 in this embodiment are then attached to the surface with a thermally conductive binder (e.g., 4450 adhesive by Corning) and then dried by an oven. However, this does not limit the invention as various conductive binders may apply and are within the scope of protection. As a result, the design has good insulation (60 um), 650-volt voltage resistance and low thermal resistance. It further possesses withstanding properties against vibrations and impacts. The FPCB 3, 4 of this present invention may have multiple slots 31, 41 to provide sleeving purposes for the blades 21 of the second impeller 2 for the centrifugal fan structure. The slots 31, 41 provide sleeving of the blades 21 of the second impeller 2 to the slots 12 between the first impeller 1 and its blades 11.

The previously described multiple T.E elements 5 are positioned between the two FPCBs 3, 4, in which P and N-type materials T.E element materials are soldered in sequence to the FPCBs 3, 4, combining the first, second impellers and T.E element 5 to form a thermoelectric module 100.

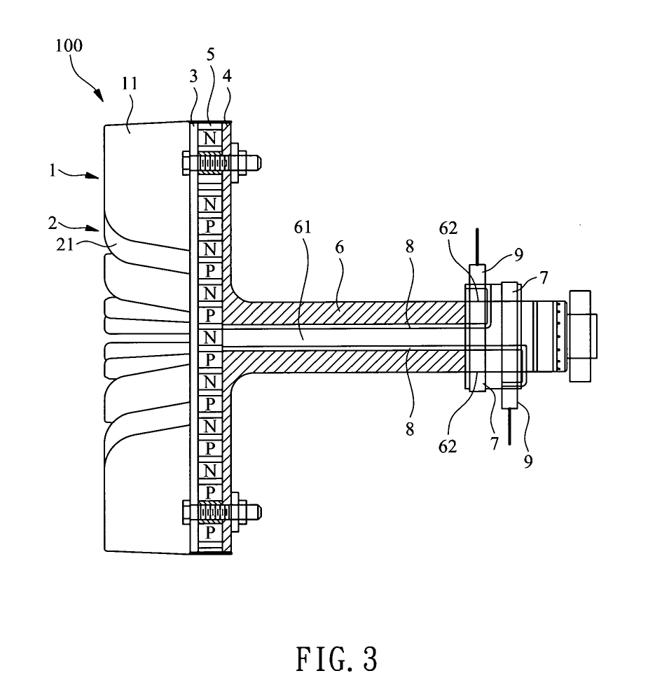

The previously described shaft 6 is positioned at the outer end of the second impeller 2 (i.e., at one end of the T.E module unit). The fastening method may be done by either screw fixing or soldering. An insulating sleeve is installed between the fixture and T.E element 5, and a waterproof seal is applied to the external side of the T.E element 5 (as in FIG. 3). Moreover, in order to overcome the distance limitations of customary modules, the shaft 6 in this present invention is a thermally conductive rod shape, which includes an axial perforating aperture and insulation layer respectively at the center and rim. The aperture 61 enables the electric current to flow through while the thermoelectric module 100 is operating and the insulation layer 62 prevents the occurrence of short circuits. The shaft 6 can be made from thermally conductive metal materials. However, it is not limited to only metal and may apply to any thermally conductive materials to be within the scope of protection. Furthermore, the shaft 6 of the present invention provides a rotational driving force to the opposite end of the impeller blade to make the thermoelectric module 100 perform rotation. At the same time, the shaft 6 is made from materials with good thermal conductivity and therefore transfers the heat of the thermoelectric module 100 from its original end to the opposite end. This heat-electricity conversion by the thermoelectric module 100 is very important among applications. Because of this thermally conductive shaft 6, the distance between the thermoelectric module 100 and thermal source is no longer restricted as with conventional modules and may bring to unlimited possibilities. Examples include the structure of a cooling pump driven by recycled from a car engine, or recycled heat from engine exhaustion. In addition, the function can also be widely used towards geothermal applications, industrial emissions and the recycling of other waste heat to convert into electrical energy.

The previously described two slip rings 7 are located at the insulation layer 62 of the shaft 6, to form an annular body which has good electro conductive and wear resistance properties.

The previously described two wires 8 are inside the aperture 61 at the shaft 6 center. The wires 8 are covered with an insulation layer, and the two ends are respectively attached to the ends of the T.E elements 5 and two slip rings 7 for connection.

The previously described two brushes 9 are installed at the slip ring 7 to form a loop with the external circuit.

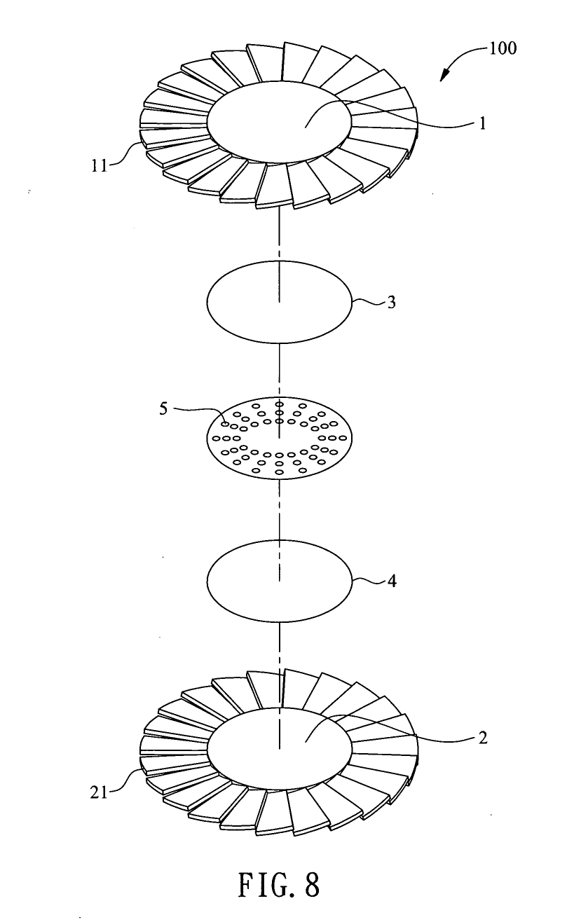

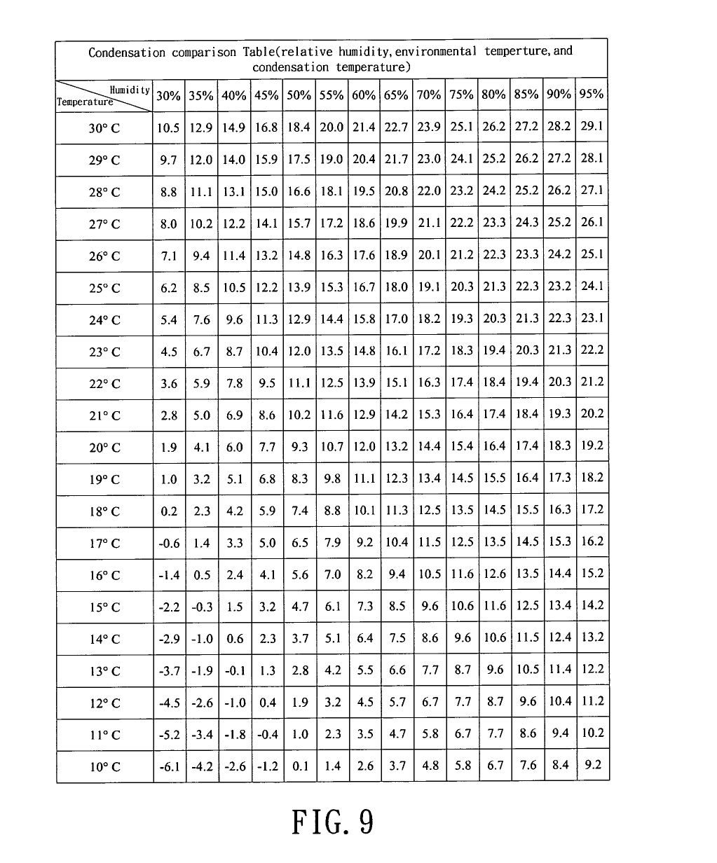

Referring to FIGS. 7, 7A and 8, the continuous contact of the operating sequence by blades 11, 21 of the first 1 and second impeller 2 makes the air flow (shown by the arrows) first blow through the cold (hot) end of the first 1 impeller blade 11 surface with its combined T.E element 4, and then blowing through the hot (cold) end of the secondary blade 21 surface of the combined second impeller 2 and T.E element 4. The design specially enhances the capability of dehumidification and water reclamation (as shown in the Condensation Table—relative humidity, environmental temperature, and condensation temperature in FIG. 9). The table shows the corresponding relation between the environmental temperature and condensation point. During the operation, the air flow first blows through the hot end surface and is heated by the heat dissipation at the hot end. On the other hand, the waste heat at the hot end is utilized and gradually vanishes. The heated air flow then passes the cold end surface, which the moisture and water vapor in the air condenses to water as it contacts the cold end surface. The condensed droplets are then removed along the tangent line of the circumferential surface by the self-centrifugal force of the impeller blades 11, 21, which are then collected and recycled. The operating process of the present invention is very fast with an extremely high efficiency. Furthermore, the invention provides a large beneficiary according to the Condensation Table, which is the large extension of temperature range. For example, the present invention is still capable to maintain a high operating performance for dehumidification or water reclamation in a scourging desert or cold winters.

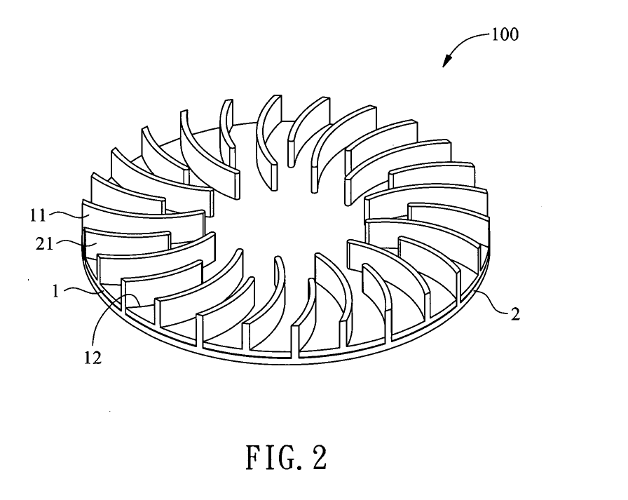

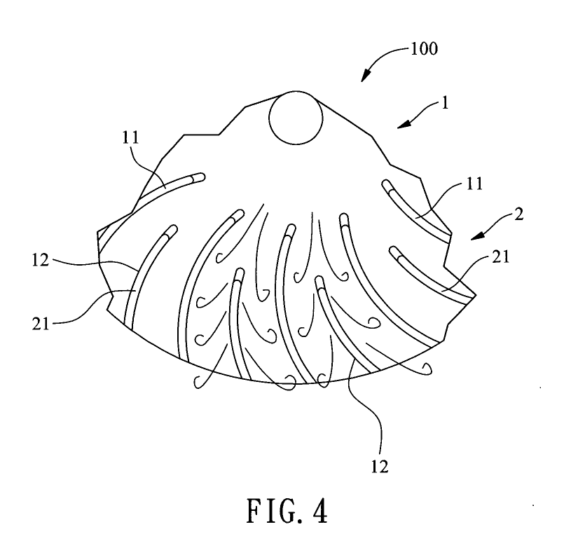

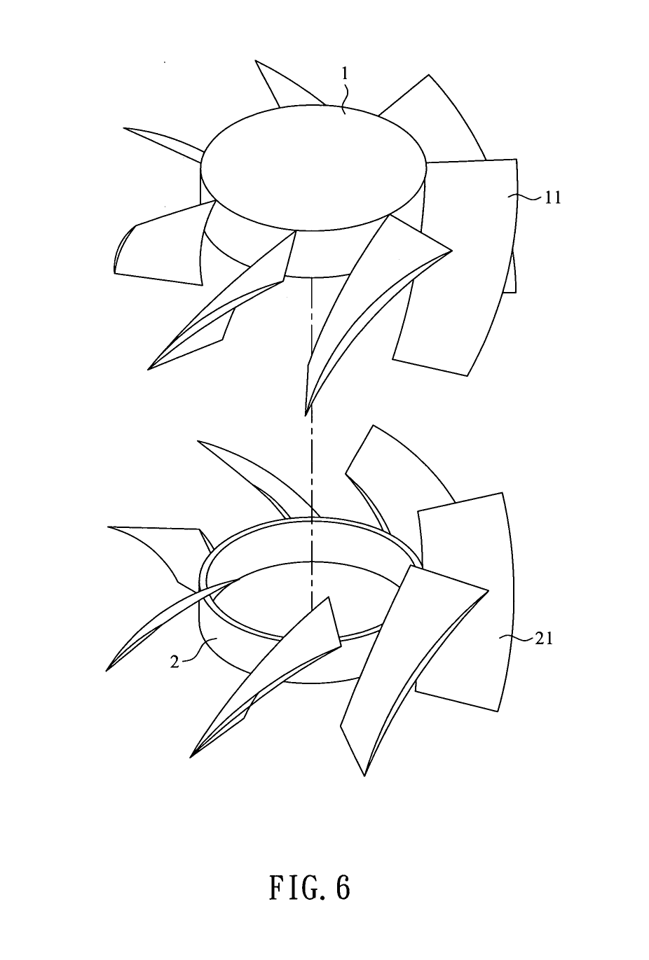

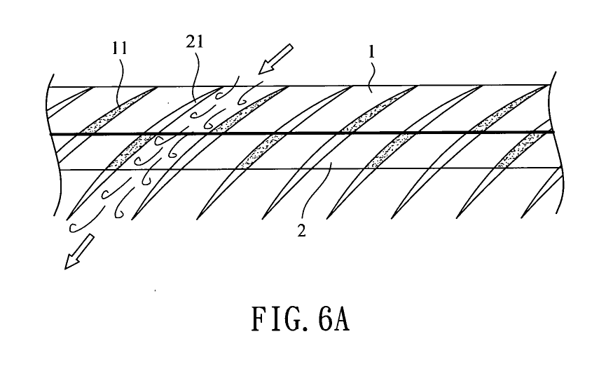

Referring now to FIGS. 1, 2, 4, 5, 6, and 6A, besides of the previous function with its cross-sequence arrangement, the cold and hot air within the air flow are well mixed and achieve turbulence (as shown by the arrows in FIGS. 4 and 6A) by the overlapping and extension of the cold and hot ends through the combined first 1, second 2 impellers and T.E elements 5. This is achieved by both fan structures, such as the long and short impeller blades 11, 21 (as in FIG. 2) in the centrifugal fan, and the overlapping and extension of the impeller blades 11, 21 of the axial fan structure, i.e. the first 1 impeller blades 11 are positioned at the peripherals of the external side and extend downwards, whereas the second 2 impeller blades 21 at the external side respectively extends upwards and downwards. As a result, as the blades combine with each other, the second 2 impeller blades 21 will extend upwards and position between two consecutive blades 11, 11 of the first impeller 1, and the second 2 impeller blades 21 extending downwards are positioned between the two consecutive blades 11 of the second impeller 2 which corresponds to the first impeller 1 (as in FIGS. 6&6A).

With this design, the present invention is able to convert the existing kinetic energy within the waste heat into the required rotational energy for the thermoelectric module 100 and achieve the heat dissipation performance of a fan. The design consumes no external electricity, saves saving, reduces carbon emission, and enhances the scope of applications and performance. The invention further overcomes the stationary structure of customary modules, and changes into a heat dissipation structure based on fan impellers, combining with slip rings 7, brushes 9 and a thermally conductive shaft 6. The benefits of the invention meet to the objectives with novelty, improvement, practical use, innovation and fits to the needs in the industry.

From the above description, it can be seen that the present invention has truly obtained and enhanced the performance based on past technical structures, which is also easy for those unfamiliar with the ordinary skill in the art to understand. In addition, the present invention has never been announced before this patent application, which the features in improvement and practical use all conform to the conditions for patent application. Therefore this application based on the related regulations to apply for a patent. We hope and show the most gratitude that your most honorable agency may approve the application to encourage continuous inventions.

The description of the above embodiment only describes the technological concept and features of this present invention, which is purposed to enable those familiar with the ordinary skill in the art can understand the contents of this present invention and to implement. The above description is only for the preferred embodiment of the present invention, and should not be limited to the scope of the present invention. Any simple equivalent changes or modifications within the scope of the present invention and description remain to be within the scope of this invention.

1. A multi-purpose high performance thermoelectric module comprising:
A first impeller with multiple blades, with the blades positioned at the end surface of a centrifugal fan, and having slots between the impeller blades;
A second impeller located at the opposite side of the first impeller, with its multiple blades corresponding to the slots of the first impeller blades, and positioned at the end surface of a centrifugal fan;
Two FPCBs which are respectively installed between the first and second impellers, with said FPCB having slots corresponding to the blades of the second impeller;
Multiple T.E elements installed between the two FPCBs, in which the T.E elements of P and N-type materials are soldered in sequence to the FPCBs of the first and second impellers by reflow, and forming the thermoelectric module;
A shaft at the outer end of the second impeller, a thermally conductive rod shape, which includes an axial perforating aperture and insulation layer respectively at the center and rim;
Two slip rings located at the insulation layer of the shaft as conductive annular bodies;
Two wires inside the aperture of the shaft, with the two ends of the wires respectively attached to the ends of the T.E elements and two slip rings for connection;
Two brushes installed at the slip ring to form a loop with the external circuit.

2. The multi-purpose high performance thermoelectric module according to claim 1, wherein the first impeller is made from a metal material.

3. The multi-purpose high performance thermoelectric module according to claim 1, wherein the second impeller is made from a metal material.

4. The multi-purpose high performance thermoelectric module according to claim 2, wherein the second impeller is made from a metal material.

5. A multi-purpose high performance thermoelectric module comprising:
A first impeller with multiple blades, with the blades positioned at the external sides of an axial fan;
A second impeller located at the opposite side of the first impeller, with its multiple blades corresponding to the first impeller blades, and positioned at the external sides of an axial fan;
Two FPCBs which are respectively installed between the first and second impellers;
Multiple T.E elements installed between the two FPCBs, in which T.E elements of P and N-type materials are soldered in sequence to the FPCBs of the first and second impellers by reflow, and forming the thermoelectric module;
A shaft at the outer end of the second impeller, a thermally conductive rod shape, which includes an axial perforating aperture and insulation layer respectively at the center and rim;
Two slip rings located at the insulation layer of the shaft as conductive annular bodies;
Two wires inside the aperture of the shaft, with the two ends of the wires respectively attached to the ends of the T.E elements and two slip rings for connection;
Two brushes installed at the slip ring to form a loop with the external circuit.

6. The multi-purpose high performance thermoelectric module according to claim 5, wherein the first impeller is made from a metal material.

7. The multi-purpose high performance thermoelectric module according to claim 5, wherein the second impeller is made from a metal material.

8. The multi-purpose high performance thermoelectric module according to claim 6, wherein the second impeller is made from a metal material.

9. The multi-purpose high performance thermoelectric module according to claim 5, wherein the blades among the first and second impellers are arranged in a cross-sequence structure.

10. The multi-purpose high performance thermoelectric module according to claim 6, wherein the blades among the first and second impellers are arranged in a cross-sequence structure.

11. The multi-purpose high performance thermoelectric module according to claim 7, wherein the blades among the first and second impellers are arranged in a cross-sequence structure.

12. The multi-purpose high performance thermoelectric module according to claim 8, wherein the blades among the first and second impellers are arranged in a cross-sequence structure.
